(19) United States
(12) Patent Application Publication
(10) Pub. No.: US 2026/0097832 A1
(43) Pub. Date: Apr. 9, 2026

(54) DESIGN METHOD FOR PASSIVE SIMULATOR OF FULL SPACE ECHO CHARACTERISTICS OF UNDERWATER VEHICLE

(71) Applicant: Jiangsu University of Science and Technology, Zhenjiang (CN)

(72) Inventors: Zilong PENG, Zhenjiang (CN); Chang WU, Zhenjiang (CN); Liwen TAN, Zhenjiang (CN); Jiaman DU, Zhenjiang (CN); Wenhui XUE, Zhenjiang (CN)

(73) Assignee: Jiangsu University of Science and Technology, Zhenjiang (CN)

(21) Appl. No.: 18/919,493

(22) Filed: Oct. 18, 2024

(30) Foreign Application Priority Data
Mar. 26, 2024 (CN) 202410348343.0

(51) Int. Cl. B63B 71/10; G06F 30/15

(52) U.S. Cl. CPC B63B 71/10; G06F 30/15

(57) ABSTRACT

A design method for a passive simulator of full-space echo characteristics of an underwater vehicle includes: obtaining a target strength color map of the divided grid of the vehicle surface, and conducting a color interpolation on the divided grid, so as to obtain the distribution cloud map of the bright spot area contributed by the target strength of the underwater vehicle surface; dividing the scale model of the underwater vehicle into the bow, the midship and the stern, and retaining a contribution area to form the partial model of the bow, the midship and the stern; designing the partial simulator of each partial model, and determining the linear array of each partial simulator to form the underwater vehicle simulator; according to the time domain echo of the simulated underwater target, placing the bow, midship and stern simulator structures, and conducting the overall simulator design of the underwater target.

### CROSS REFERENCE TO THE RELATED APPLICATIONS

This application is based upon and claims priority to Chinese Patent Application No. 202410348343.0, filed on Mar. 26, 2024. The entire contents of this application are incorporated herein by reference.

### TECHNICAL FIELD

The invention relates to the field of underwater acoustic engineering technology, specifically to a design method for a passive simulator that emulates the full-space echo characteristics of an underwater vehicle.

### BACKGROUND

Acoustic simulators are categorized into active and passive modes. The active acoustic simulator employs strong energy suppression or copy forwarding to execute underwater acoustic countermeasure. Specifically, it utilizes a receiving response mode to simulate the acoustic reflection of the underwater vehicles by receiving and processing active acoustic detection signals before retransmission. Multiple transponder array elements are utilized to simulate the echo bright spot of underwater target, enabling scale simulation of these targets.

In contrast, passive acoustic simulators do not emit acoustic signals; instead, they simulate or suppress the scattering sound field of active sonar signals through false echoes or strong clutter echoes generated by passive jammers or simulators. This mechanism effectively disrupts the detection and recognition capabilities of active sonar. Passive acoustic simulators offer several advantages, including fast response time, reduced risk of exposure, lightweight design, low cost and enhanced maneuverability, positioning them as the future trend in underwater acoustic countermeasures.

Compared to point source acoustic simulator, the multiple acoustic primitives of linear array acoustic simulators can more effectively simulate the scale and azimuth extension characteristics of targets. As a countermeasure tool capable of scale simulation, linear array acoustic simulators have demonstrated significant success in this domain. Consequently, enhancing the fidelity of linear array acoustic simulators remains a key focus of research in underwater countermeasures. Currently, the mechanisms and design methodologies for linear array acoustic simulators within the context of passive underwater acoustics are largely unexplored. Thus, there is an urgent need to investigate new structures, scattering sound field simulations, control mechanisms, and operational modes for passive acoustic simulators, which will provide a theoretical foundation for the development of the next generation of such technologies.

### SUMMARY

Purpose of the invention: Addressing the shortcomings of the existing technology and the structures of passive acoustic simulators, this invention proposes a design method for a passive simulator that emulates the full-space echo characteristics of underwater vehicles. This method aims to facilitate the application of small-scale passive acoustic simulators in simulating the echo characteristics of underwater vehicles.

Technical scheme: The design method for the passive simulator of the full-space echo characteristics of underwater vehicles includes the following steps:
(1) Based on a typical underwater vehicle model, this method involves obtaining a target strength color map of a divided grid on the vehicle's surface and performing color interpolation on the colors of the divided grid. This process smooths the color representation of the vehicle's surface in terms of the target strength, resulting in a distribution cloud map of the bright spot areas contributed by the target strength of the underwater vehicle surface. According to the distribution cloud maps of the bright spot areas at multiple incident angles (where the main contribution area of the echo is the bright spot area), the scale model of the underwater vehicle is divided into the bow, the midship and the stern. Non-contribution areas of the bow, the midship and the stern are then cut and removed, leaving only the contribution areas to form partial models of the bow, midship and stern.
(2) Conducting structural design according to the bow of the partial model involves retaining the contour lines of an xoy plane semi-ellipse, a zoy plane circle and an xoz plane semi-ellipse of the bow. The bow of the partial model is then cut and removed to form a four-grid-corner reflector structure composed of arc-shaped plates, which serves as the bow simulator.
(3) Conducting structural design according to the midship of the partial model involves retaining contour lines of an xoy plane square, a zoy plane circle and an xoz plane square of the midship. The midship of the partial model is then cut and removed to form a twenty-grid-corner reflector structure with an arc shape, which serves as the midship simulator.
(4) Conducting structural design according to stern of the partial model involves retaining contour lines of an xoy plane trapezoid, a zoy plane trapezoid and an xoz plane trapezoid of the stern. The stern of the partial model is then cut and removed to form a four-grid-corner reflector composed of trapezoidal and arc-shaped plates.
(5) Based on the time-domain echo of a simulated underwater target, the bow, midship and stern simulator structures designed in previous steps (2)-(4) are placed in their corresponding positions to create an overall simulator design for the simulated underwater target.
(6) When applying the designed overall simulator structure of the underwater target in the underwater, a fixed-depth towed body is used to determine the underwater position of the overall simulator.

In step (1), using planar element method (Kirchhoff Approximation) to obtain the target strength color map of the divided grid of the underwater vehicle surface.

In step (1), using a shading interp in Matlab to conduct the color interpolation on the divided grid.

In step (1), dividing the scale model of the underwater vehicle into the bow, the midship and the stern according to the distribution cloud maps of the bright spot areas at incident angles of 0°, 45°, 90°, 135° and 180°.

In step (2), according to a plane parallel to contour lines of xoy, zoy and xoz planes, cutting and removing the bow of the partial model to form a four-grid-corner reflector-like bow simulator composed of arc-shaped plates.

In step (3), according to the plane parallel to the contour lines of the xoy, zoy and xoz planes, cutting and removing the midship of the partial model to form a twenty-grid-corner reflector-like midship simulator composed of arcs.

In step (4), according to the plane parallel to the contour lines of the xoy, zoy and xoz planes, conducting cutting and removing to form a four-grid-corner reflector composed of trapezoidal and arc-shaped plates.

In step (6), the underwater position of the simulator includes a depth and a distance.

A corner reflector structure is composed of multiple concave surfaces.

The concave surface is composed of multiple plates connected to each other, and the connection angles are right angle, acute angle and obtuse angle.

Working principle: The design method for the passive simulator divides the underwater vehicle into the bow, the midship and the stern, forming a partial model of the combination of the bow, the midship and the stern, that is, the partial simulator of the bow, the midship and the stern, and then the linear array of each partial simulator constitutes an underwater vehicle simulator. The partial model serves as a simplified representation of underwater vehicle segmentation. The bow, midship and stern of the partial simulator are multi-grid-corner reflector simulator. The underwater vehicle simulator is composed of a bow simulator, a midship simulator and a stern simulator, each consisting of multiple passive acoustic multi-grid-corner reflectors, where the multi-grid-corner reflector comprises multiple concave surfaces.

Then, a partial acoustic simulator simulator is designed, and then an array of each part of the acoustic simulator is combined to form the partial acoustic simulator of the underwater vehicle.

Among them, a passive simulator design of the bow, midship and stern partial model is based on the contour lines of the xoy, xoz, and zoy planes to design the corresponding multi-grid-corner reflector simulator structure of the partial model.

The passive simulator proposed in this invention primarily employs a multi-grid-corner reflector structure, complemented by auxiliary components to accurately simulate the characteristics of underwater targets. By utilizing the echo characteristics of the underwater vehicle, the position of the linear array of the passive simulator—located at the bow, midship, and stern—are determined. To ensure heading stability during towing, the simulator is equipped with a streamlined flow-guiding cover, which minimizes turbulence-induced interference with the acoustic simulator structure.

The corner reflector assembly consists of multiple concave configurations. Each concave surface is made up of several interconnected plates, with connection angles that include right, acute and obtuse angles. The shape of each concave configuration features a range of geometric forms, including squares, arcs, and triangles, which correspond to the contour of the simulated target. Each partial simulator is constructed from a multi-grid-corner reflector, with the corner reflector itself consisting of multiple planar surfaces of varying shapes.

Beneficial effects: compared with the existing technology, the invention has the following advantages:
(1) The design method for the passive simulator of the invention grasps the reconstruction and optimization method of the statistical characteristics of the scattering sound field of the underwater target at the technical level, and realizes the reconstruction of the scattering sound field of the complex target in the water in the statistical sense.
(2) The invention lays a solid foundation for the design and development of passive acoustic simulator in underwater acoustic countermeasure.
(3) The design method of the invention provides reference and design idea for the design of passive acoustic simulator of underwater vehicle.

### BRIEF DESCRIPTION OF THE DRAWINGS

FIG. 1 is the schematic diagram of the design structure of the passive simulator of the full space echo characteristics of the underwater vehicle of the invention.

FIG. 2 is a three-view contour line diagram of the underwater vehicle of the invention;

FIG. 3 is the schematic diagram of the composite sandwich structure designed by the passive simulator of the invention;

FIG. 4 is the schematic diagram of the underwater target simulator of the linear array of the invention.

FIG. 5 is the schematic diagram of the calculation target working condition of the invention.

FIG. 6 is the comparison diagram of the strength directivity of the simulated underwater target and the simulator of the invention.

FIG. 7 is the contrast diagram of the echo bright spot of the simulated underwater target of the invention.

### DETAILED DESCRIPTION OF THE EMBODIMENTS

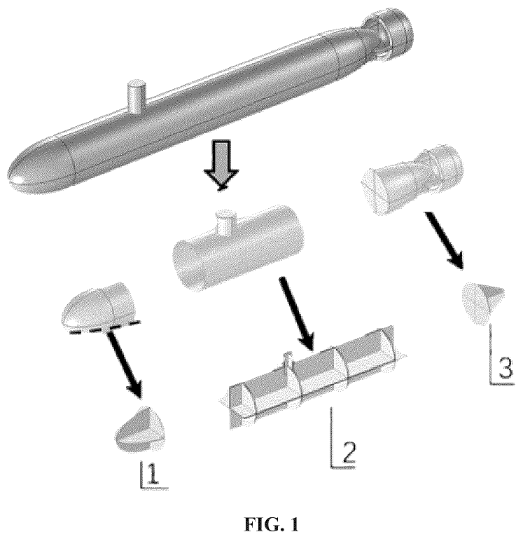

The passive simulator structure designed by the design method for the passive simulator of the underwater vehicle of the invention is shown in FIG. 1, the passive simulator is composed of a multi-grid corner reflector to form a linear array of the simulator of the bow 1, the midship 2 and the stern 3.

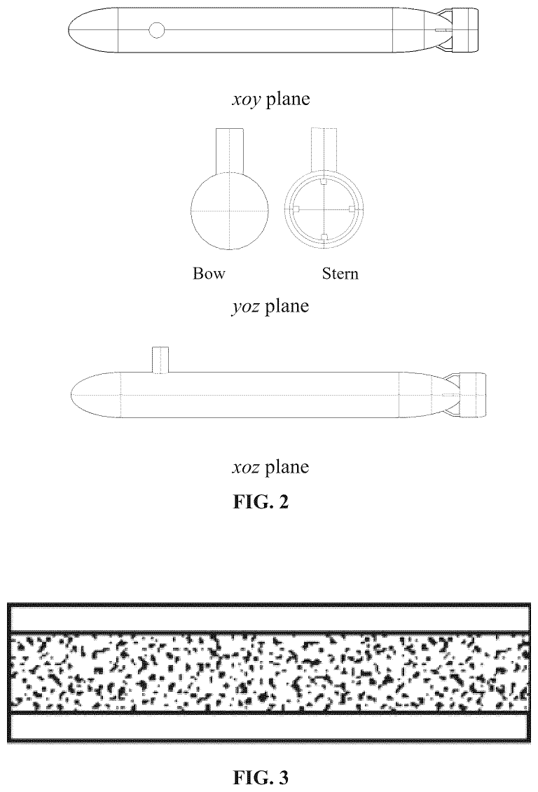

In this invention, the contour design of the bow, midship, and stern simulator models relies on the outer contour of the underwater vehicle as shown in FIG. 1. Based on the outer contour of the underwater vehicle, such as the three-view contour map of the simulated target in FIG. 2, according to the plane parallel to the contour lines of the xoy, zoy, and xoz planes, the bow, midship, and stern simulator models are designed by cutting and removing.

The bow 1 simulator is a four-grid-corner reflector composed of a semi-elliptical shape of the xoz and xoy planes and a circular shape of the zoy plane.

The midship 2 simulator is a twenty-grid-corner reflector composed of a square shape of xoz and xoy planes and a circular shape of zoy plane.

The stern 3 simulator is a four-grid-corner reflector composed of a trapezoidal shape of xoz and xoy planes and a circular shape of zoy plane.

The linear array underwater target simulator of bow 1, midship 2 and stern 3 is the same as the echo space position of the simulated target, which is in the x-axis direction of the array.

As shown in FIG. 3, as the preferred scheme of the invention, according to the underwater target simulator designed by the invention, the composite sandwich structure material with anti-sound performance used in the underwater target simulator is determined, the material includes buoyancy material or filled air, which realizes the strong reflection effect and ensures the underwater lightweight weak positive buoyancy state of the simulator.

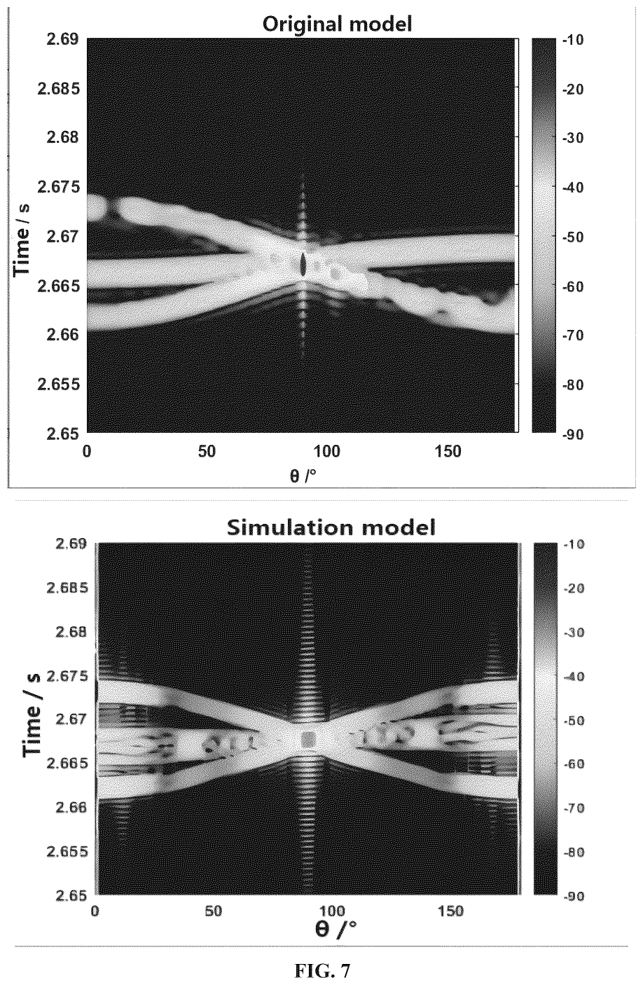

As the preferred scheme of the invention, according to the underwater target simulator of the structure and material determined above, as shown in FIG. 6, the target strength directivity is compared with the simulator, and as shown in FIG. 7, the acoustic scattering characteristics of the echo broadening diagram are compared. The echo characteristics include time domain echo characteristics, target strength directivity characteristics and echo bright spot characteristics.

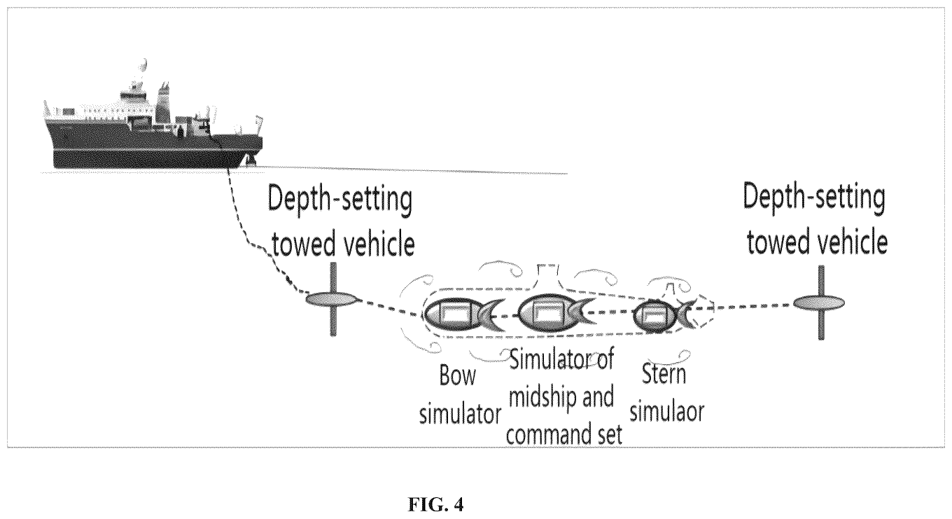

As the preferred scheme of the invention, the design method of the target simulator of the invention is applied to the simulation of the acoustic scattering characteristics of the underwater target, as shown in FIG. 4, a tugboat or a small underwater unmanned vehicle is used to tow.

### Embodiment

As shown in FIG. 2, according to the plane parallel to the contour lines of the xoy, zoy and xoz planes, the original model of the underwater simulated target and the contour lines of the xoy, xoz and zoy planes of the original model of the underwater simulated target of the invention are simplified and divided into the partial model of the bow, midship and stern. Based on the bow, midship and stern contour lines of the partial model, the structure of the bow, midship and stern partial model is designed. The time domain echo of the original model of the underwater simulated target is used to judge the layout diagram of the partial simulator, as shown in FIG. 1. Then, the above designed partial simulator is used, and the rigid-cavity-rigid is also used as the interlayer, as shown in FIG. 3, the target strength directivity of the original model of the underwater target is simulated, as shown in FIG. 6; the time domain echo broadening diagram is shown in FIG. 7.

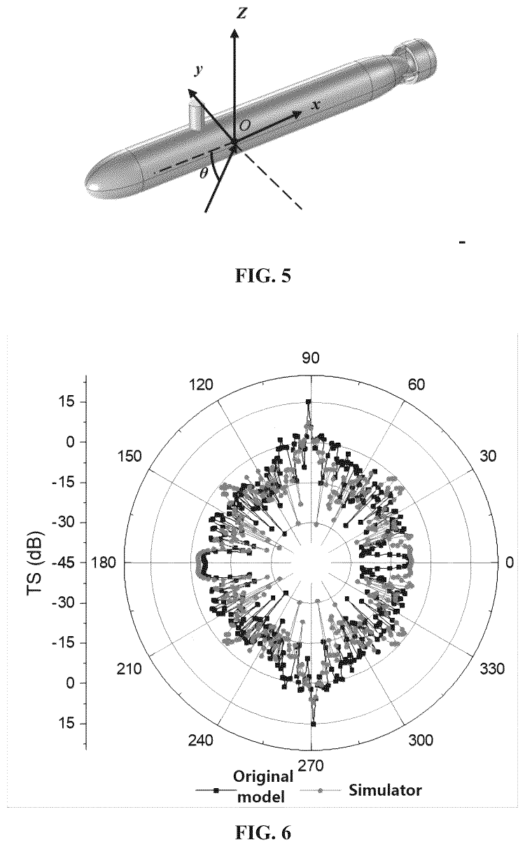

The calculation condition is shown in FIG. 5, and the geometric center of the underwater target is taken as the coordinate origin. When the calculation frequency is 5 kHz and the xoy plane θ=0°-360°, the target strength directivity of the underwater target simulator and the original model is compared, according to FIG. 6, the target strength directivity of the original model and the designed underwater target simulator is in good agreement. As shown in FIG. 7, it is a single-frequency incident signal, when the calculation frequency is 5 kHz and the xoy plane θ=0°-180°, the comparison of the underwater target simulator and the echo broadening diagram of the original model shows that the simulation effect of the characteristics of the bow, midship and stern is good in the angle range of θ=0 °-180°.

What is claimed is:

1. A design method for a passive simulator of full space echo characteristics of an underwater vehicle, comprising the following steps:
(1) based on a typical underwater vehicle model, obtaining a target strength color map of a divided grid of an underwater vehicle surface, and conducting a color interpolation on a color of the divided grid, so as to smooth a color of the underwater vehicle surface representing a target strength and obtain a distribution cloud map of a bright spot area contributed by the target strength of the underwater vehicle surface; according to distribution cloud maps of bright spot areas at multiple incident angles, dividing a scale model of the underwater vehicle into a bow, a midship and a stern, dividing and removing a non-contribution area of the bow, the midship and the stern, and retaining a contribution area to form a partial model of the bow, the midship and the stern;
(2) conducting a first structure design according to the bow of the partial model, retaining contour lines of an xoy plane semi-ellipse, a first zoy plane circle and an xoz plane semi-ellipse of the bow, and cutting and removing the bow of the partial model to form a four-grid-corner reflector structure composed of arc-shaped plates to serve as a bow simulator;
(3) conducting a second structure design according to the midship of the partial model, retaining contour lines of an xoy plane square, a second zoy plane circle and an xoz plane square of the midship, and cutting and removing the midship of the partial model to form a twenty-grid-corner reflector structure with an arc shape to serve as a midship simulator;
(4) conducting a third structure design according to stern of the partial model, retaining contour lines of an xoy plane trapezoid, a zoy plane trapezoid and an xoz plane trapezoid of the stern, and conducting cutting and removing to form a four-grid-corner reflector composed of trapezoidal and arc-shaped plates to serve as a stern simulator;
(5) according to a time domain echo of a simulated underwater target, placing the bow simulator, the midship simulator and the stern simulator designed in above steps (2)-(4) respectively in bow, midship and stern simulator positions corresponding to the simulated underwater target, and conducting an overall simulator design of the simulated underwater target to obtain a designed overall simulator structure;
(6) when the designed overall simulator structure of the simulated underwater target is applied in the underwater, using a fixed-depth towed body to determine an underwater position of an overall simulator.

2. The design method for the passive simulator of the full space echo characteristics of the underwater vehicle according to claim 1, wherein in step (1), a plate element calculation method is used to obtain the target strength color map of the divided grid of the underwater vehicle surface.

3. The design method for the passive simulator of the full space echo characteristics of the underwater vehicle according to claim 1, wherein in step (1), a shading interp in Matlab is used to conduct the color interpolation on the color of the divided grid.

4. The design method for the passive simulator of the full space echo characteristics of the underwater vehicle according to claim 1, wherein in step (1), the scale model of the underwater vehicle is divided into the bow, the midship and the stern according to the distribution cloud maps of the bright spot areas at incident angles of 0°, 45°, 90°, 135° and 180°.

5. The design method for the passive simulator of the full space echo characteristics of the underwater vehicle according to claim 1, wherein in step (2), according to a plane parallel to contour lines of xoy, zoy and xoz planes, the bow of the partial model is cut and removed to form the four-grid-corner reflector structure composed of arc-shaped plates to serve as the bow simulator.

6. The design method for the passive simulator of the full space echo characteristics of the underwater vehicle according to claim 1, wherein in step (3), according to a plane parallel to contour lines of xoy, zoy and xoz planes, the midship of the partial model is cut and removed to form the twenty-grid-corner reflector structure composed of arcs to serve as the midship simulator.

7. The design method for the passive simulator of the full space echo characteristics of the underwater vehicle according to claim 1, wherein in step (4), according to a plane parallel to contour lines of xoy, zoy and xoz planes, cutting and removing are conducted to form the four-grid-corner reflector composed of trapezoidal and arc-shaped plates to serve as the stern simulator.

8. The design method for the passive simulator of the full space echo characteristics of the underwater vehicle according to claim 1, wherein in step (6), the underwater position of the overall simulator comprises a depth and a distance.

9. The design method for the passive simulator of the full space echo characteristics of the underwater vehicle according to claim 1, wherein a corner reflector structure comprises a plurality of concave surfaces.

10. The design method for the passive simulator of the full space echo characteristics of the underwater vehicle according to claim 9, wherein each of the plurality of concave surfaces comprises a plurality of plates connected to each other at a right angle, an acute angle and an obtuse angle.
